(19) United States
(12) Patent Application Publication
(10) Pub. No.: US 2015/0118474 A1
(43) Pub. Date: Apr. 30, 2015

(54) SUBSTRATE RAW MATERIAL AND METHOD FOR MANUFACTURING THE SAME, AND CIRCUIT BOARD MANUFACTURED USING THE SAME

(71) Applicant: Samsung Electro-Mechanics Co., Ltd., Suwon (KR)

(72) Inventors: Jung Hwan PARK, Suwon (KR); Sung Taek LIM, Suwon (KR); Dong Hoon KIM, Sungnam (KR)

(73) Assignee: Samsung Electro-Mechanics Co., Ltd., Suwon (KR)

(21) Appl. No.: 14/162,045

(22) Filed: Jan. 23, 2014

(30) Foreign Application Priority Data
Oct. 28, 2013 (KR) 10-2013-0128615

(51) Int. Cl. H05K 1/03; B29B 15/10

(52) U.S. Cl. CPC H05K 1/036; H05K 1/038; B29B 15/10; H05K 2201/0278; H05K 2201/062; H05K 2201/068
USPC 428/221; 427/389.9

(57) ABSTRACT

The present invention relates to a substrate raw material such as a copper clad laminate for manufacturing a circuit board. A substrate raw material in accordance with an embodiment of the present invention includes an insulating layer and an organic fiber cloth disposed in the insulating layer.

### CROSS-REFERENCE TO RELATED APPLICATIONS

This application claims the foreign priority benefit of Korean Patent Application No. 10-2013-0128615 filed Oct. 28, 2013, the contents of which are incorporated herein by reference.

### BACKGROUND

1. Field

The present invention relates to a substrate raw material and a method for manufacturing the same, and a circuit board manufactured using the same, and more particularly, to a substrate raw material, which has excellent thermal and mechanical stability to improve signal transmission characteristics at high speed and high frequency band, and a method for manufacturing the same, and a circuit board manufactured using the same.

2. Description of the Related Art

In recent times, as electronic devices have been rapidly developed and a frequency band used in telecommunications equipment becomes higher, printed circuit boards applied to these electronic devices also become smaller, thinner, and multifunctional. In these technical trends, electrical, thermal, and mechanical stability and reliability of the printed circuit board are very important factors, and particularly, in a manufacturing process of the circuit board, a coefficient of thermal expansion (CTE) contributing to thermal deformation is a very important factor in terms of stability and reliability of the final product.

Meanwhile, a mounting board, which directly connects a semiconductor chip and a main board, also has been developed with the trend of miniaturization, high speed, and high density. Due to this, there are also increasing problems such as warpage due to heat and bad solder joint reliability due to a CTE mismatch between the semiconductor chip and the mounting board. In addition, there is a need for a semiconductor chip mounting board having a low permittivity to transmit a high frequency electrical signal without loss and minimize interference between circuits.

However, in order to achieve high density and high speed of the above-described circuit boards, improvements in the CTE and low permittivity characteristics of a copper clad laminate (CCL) or prepreg, which is a raw material of the circuit boards, should be essentially supported.

### RELATED ART DOCUMENT

### Patent Document

Patent Document 1: Japanese Patent Laid-Open No. 2004-029080

### SUMMARY

The present invention has been invented in order to overcome the above-described problems and it is, therefore, an object of the present invention to provide a substrate raw material, which can improve thermal and mechanical stability of a circuit board, and a circuit board manufactured using the same.

It is another object of the present invention to provide a substrate raw material, which has excellent thermal and mechanical stability to be used at high speed and high frequency band, and a circuit board manufactured using the same.

It is another object of the present invention to provide a method for manufacturing a substrate raw material, which can improve thermal and mechanical stability of a circuit board.

It is another object of the present invention to provide a method for manufacturing a substrate raw material, which has excellent thermal and mechanical stability to be used at high speed and high frequency band.

In accordance with one aspect of the present invention to achieve the object, there is provided a substrate raw material for manufacture of a circuit board, including: an insulating layer and an organic fiber cloth disposed in the insulating layer.

In accordance with an embodiment of the present invention, the insulating layer may have a coefficient of thermal expansion of less than 5.0 ppm/° C.

In accordance with an embodiment of the present invention, the insulating layer may have a coefficient of thermal expansion of not more than 1.0 ppm/° C.

In accordance with an embodiment of the present invention, the insulating layer and the organic fiber cloth may be made of a polymer resin.

In accordance with an embodiment of the present invention, the organic fiber cloth may be made of at least one super engineering polymer resin of polysulfone (PSU), polyetherimide (PEI), polyethersulfone (PES), polyphenylsulfone (PPSU), and polyamideimide (PAI).

In accordance with an embodiment of the present invention, the organic fiber cloth may be made of at least one super engineering polymer resin of polyphenylsulfone (PPSU), polyetheretherketone (PEEK), and polyphthalamide (PPA), which has a melting point or a glass transition temperature of not less than 280° C.

In accordance with an embodiment of the present invention, the substrate raw material may be a copper clad laminate for manufacture of a circuit board, which is used in a high frequency band of not less than 1 MHz.

In accordance with an embodiment of the present invention, the substrate raw material may be a prepreg for manufacture of a circuit board, which is used in a high frequency band of not less than 1 MHz.

In accordance with another aspect of the present invention to achieve the object, there is provided a circuit board including: a core layer manufactured by processing a prepreg and a circuit layer disposed on the core layer, wherein the core layer includes an insulating layer made of a resin material and an organic fiber cloth disposed in the insulating layer.

In accordance with an embodiment of the present invention, the insulating layer may have a coefficient of thermal expansion of less than 5.0 ppm/° C.

In accordance with an embodiment of the present invention, the insulating layer may have a coefficient of thermal expansion of not more than 1.0 ppm/° C.

In accordance with an embodiment of the present invention, the insulating layer and the organic fiber cloth may be made of a polymer resin.

In accordance with an embodiment of the present invention, the organic fiber cloth may be made of at least one super engineering polymer resin of polysulfone (PSU), polyetherimide (PEI), polyethersulfone (PES), polyphenylsulfone (PPSU), and polyamideimide (PAI).

In accordance with an embodiment of the present invention, the organic fiber cloth may be made of at least one super engineering polymer resin of polyphenylsulfone (PPSU), polyetheretherketone (PEEK), and polyphthalamide (PPA), which has a melting point or a glass transition temperature of not less than 280° C.

In accordance with another aspect of the present invention to achieve the object, there is provided a method for manufacturing a substrate raw material, including: manufacturing an organic fiber cloth using a super engineering polymer resin and manufacturing a prepreg by impregnating the organic fiber cloth with a base resin and drying the organic fiber cloth.

In accordance with an embodiment of the present invention, the step of manufacturing the organic fiber cloth may include: manufacturing an organic fiber using at least one resin of polysulfone (PSU), polyetherimide (PEI), polyethersulfone (PES), polyphenylsulfone (PPSU), and polyamideimide (PAI); and weaving the organic fiber.

In accordance with an embodiment of the present invention, the step of manufacturing the organic fiber cloth may include: manufacturing an organic fiber using at least one resin of polyphenylsulfone (PPSU), polyetheretherketone (PEEK), and polyphthalamide (PPA), which has a melting point or a glass transition temperature of not less than 280° C.; and weaving the organic fiber.

In accordance with an embodiment of the present invention, the base resin and the organic fiber cloth may be made of the same polymer resin.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing a substrate raw material in accordance with an embodiment of the present invention;

FIG. 2 is a flowchart showing a method for manufacturing a substrate raw material in accordance with an embodiment of the present invention; and

FIGS. 3A, 3B, 4 and 5 are views for explaining a process of manufacturing a substrate raw material in accordance with an embodiment of the present invention.

### DESCRIPTION OF EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The exemplary embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. Further, terms “comprises” and/or “comprising” used herein specify the existence of described shapes, numbers, steps, operations, members, elements, and/or groups thereof, but do not preclude the existence or addition of one or more other shapes, numbers, operations, members, elements, and/or groups thereof.

Further, embodiments to be described throughout the specification will be described with reference to cross-sectional views and/or plan views, which are ideal exemplary drawings of the present invention. In the drawings, the thicknesses of layers and regions may be exaggerated for the effective explanation of technical contents. Therefore, the exemplary drawings may be modified by manufacturing techniques and/or tolerances. Therefore, the embodiments of the present invention are not limited to the accompanying drawings, and can include modifications to be generated according to manufacturing processes. For example, an etched region shown at a right angle may be formed in the rounded shape or formed to have a predetermined curvature.

Hereinafter, a substrate raw material and a method for manufacturing the same, and a circuit board manufactured using the same in accordance with embodiments of the present invention will be described in detail with reference to the accompanying drawings.

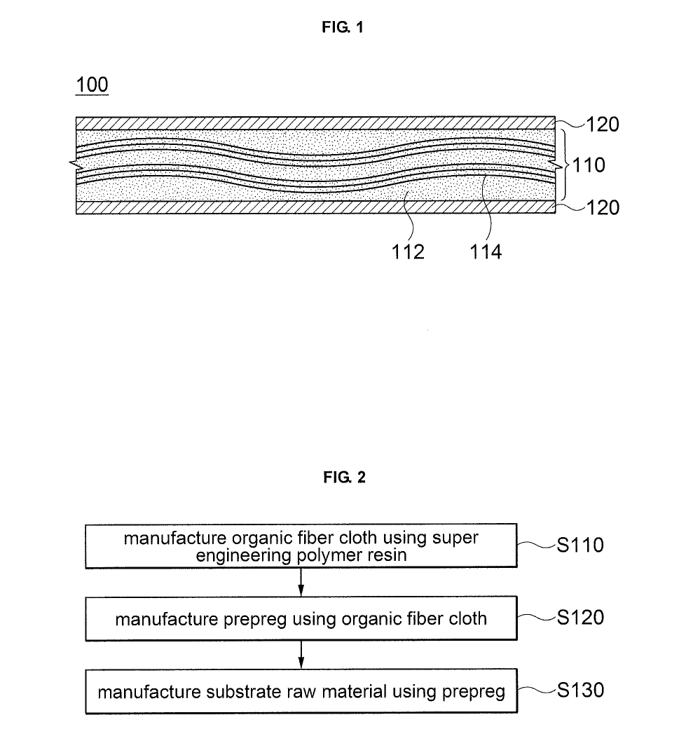

FIG. 1 is a view showing a substrate raw material in accordance with an embodiment of the present invention. Referring to FIG. 1, a substrate raw material 100 according to an embodiment of the present invention may be a copper clad laminate (CCL). The substrate raw material 100 may be a CCL for manufacture of a circuit board used in a high frequency band of not less than about 1 MHz. Further, the substrate raw material 100 may be manufactured by performing pressing and heat treatment on a laminate formed by laminating a plurality of prepregs.

The substrate raw material 100 may include an insulating layer 110 and a copper foil layer 120 which covers a surface of the insulating layer 110. The insulating layer 110 may have a resin layer 112 and an organic fiber cloth 114 disposed in the resin layer 112.

The resin layer 112 may be manufactured by performing pressing and heat treatment on the laminate formed by laminating the plurality of prepregs prepared using a resin composite which includes a resin as a main material and selectively includes other inorganic filler, binder, and additives. Preferably, the content of the inorganic filler may be about 10 wt % to 30 wt % based on the resin composite. And, preferably, the total content of the resin, the binder, and the additives may be adjusted to about 20 wt % to 30 wt %. The copper foil layer 120 is a metal film which covers at least one surface of the resin layer 112 and may become a circuit pattern of a printed circuit board through a subsequent patterning process.

The resin layer 112 may be manufactured using a composite which includes a resin as a main material. Preferably, the resin for the manufacture of the resin layer 112 may be a polymer resin having a heat-resistant property similar to the inorganic fiber cloth 114. In addition, preferably, the resin may have a melting point or a glass transition temperature of not less than about 280° C. to prevent deformation at a temperature of about 240° C. to 260° C. which is a mounting temperature of a chip component used in the circuit board.

As an example, the resin may be a super engineering polymer resin. When the resin is a super engineering polymer resin, it is possible to additionally reduce a coefficient of thermal expansion through a secondary stretching process when manufacturing a fiber using a semi-crystal polymer resin through a spinning process. This super engineering polymer resin may be at least one of polysulfone (PSU), polyetherimide (PEI), polyethersulfone (PES), polyphenylsulfone (PPSU), polyamideimide (PAI), polyetheretherketone (PEEK), and polyphthalamide (PPA).

As another example, the resin may be an epoxy resin. The epoxy resin may include an epoxy group that can form a three-dimensional structure by forming cross-linking through a reaction with a hardener in a molecule. The epoxy resins may be classified into a bisphenol type and a novolac type according to the manufacturing method. Selectively, it is possible to meet the recent lead-free or halogen-free requirements for electronic devices by containing high Tg epoxy and halogen such as bromine (Br) in the epoxy resin. The epoxy resin has a coefficient of thermal expansion (CTE) of about 70 to 100 ppm/° C. and a permittivity of greater than about 4.0. Therefore, it may be difficult to apply the epoxy resin to the thin printed circuit boards used at high speed and high frequency band, which have a very fine circuit line width, due to these material characteristics. However, since the substrate raw material manufactured using the epoxy resin as a main material has a low peel strength with a copper foil and has difficulty in uniformly dispersing a Teflon filler in the whole epoxy resin compared to the substrate raw material manufactured using the super engineering polymer resin as a main material, the finally manufactured substrate raw material has a local difference in the permittivity, thus causing problems with dielectric loss or electron transfer.

As another example, the resin may be a bismalemimde triazine (BT) resin. The BT resin has relatively higher thermal characteristics, peel strength with a copper foil, and thermal stability than the epoxy resin and thus can be used as a base resin of a semiconductor chip mounting board.

Meanwhile, in the composite according to an embodiment of the present invention, a relatively small amount of Teflon filler may be further added to the above compositions to improve thermal, mechanical, and electrical characteristics. Teflon is a material having a non-sticking property, a non-wetting property, a low coefficient of friction, chemical-resistance, and heat-resistance and may be added to the composite to improve the characteristics of the composite. The Teflon filler may be a filler made of at least one Teflon material of polytetrafluoro ethylene (PTFE), perfluoroalkoxy (PFA), fluorinated ethylene propylene (FEP), ethylene chlorotrifluoroethylene (ECTFE), ethylene tetrafluoro ethylene (ETFE), polyvinyliden fluoride (PVDF), polypropylene (PP), and polyvinyl chloride (PVC). As an example, the Teflon filler may be PTFE powder. In addition, the above composite may further include an inorganic filler as a filler for giving various properties. The inorganic filler may be silica etc.

The organic fiber cloth 114 may be a cloth made of a predetermined organic fiber. Preferably, in order to reduce a CTE, the organic fiber cloth 114 may be a resin having a melting point or a glass transition temperature of not less than about 280° C. not to be deformed at about 240° C. to 260° C. which is the mounting temperature of the chip component used in the circuit board. As an example, preferably, the resin may be a super engineering polymer resin. The super engineering polymer resin can additionally reduce the CTE through a secondary stretching process when manufacturing a fiber by spinning a semi-crystal polymer resin. This super engineering polymer resin may be polysulfone (PSU), polyetherimide (PEI), polyethersulfone (PES), polyphenylsulfone (PPSU), and polyamideimide (PAI).

As another example, the resin may be an organic polymer resin having heat resistance equal or similar to the organic polymer resin for the manufacture of the above-described resin layer 112. In this case, the organic fiber cloth 114 can minimize occurrence of glass protrusion. Here, when performing the lamination process of the prepregs to manufacture the resin layer 112, in order to prevent melting of the organic fiber cloth 114 made of organic components, the fiber may be manufactured using organic components having a melting point which is about 20° C. higher than the melting point of the resin.

The above substrate raw material 100 may be a substrate raw material for manufacturing a printed circuit board, which is manufactured by impregnating the above organic fiber cloth 114 with the polymer resin and drying the organic fiber cloth 114. Otherwise, the substrate raw material may be manufactured into a build-up film by impregnating the polymer resin in the organic fiber. Furthermore, it is possible to manufacture a printed circuit board through a typical printed circuit board manufacturing process using the substrate raw material 100 manufactured as above. For example, a method for manufacturing a printed circuit board according to an embodiment of the present invention may include the steps of making the substrate raw material 100 into a sheet using a roll, cutting the sheet raw material to a desired size, and manufacturing a substrate raw material for sale by attaching a carrier film and a protection film to the sheet. And, in the process of manufacturing the printed circuit board, a predetermined printed circuit board can be manufactured by removing the carrier film and the protection film from the sheet, performing processes such as exposure, development, corrosion, stripping, and drying on the sheet to form a circuit pattern, and performing a post-process. This printed circuit board may include a core layer manufactured by the substrate raw material 100 and a circuit layer laminated on at least one surface of the core layer and having a circuit pattern thereon. The circuit layer may have a circuit pattern formed by patterning the copper foil layer 120 of the substrate raw material 100.

Continuously, a method for manufacturing a substrate raw material in accordance with an embodiment of the present invention will be described in detail. Here, duplicate descriptions of the substrate raw material 100 in accordance with an embodiment of the present invention may be omitted or simplified.

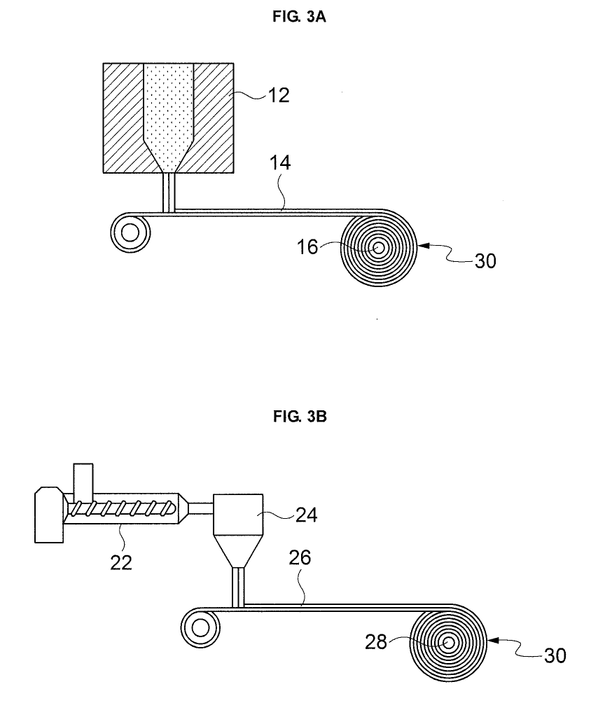

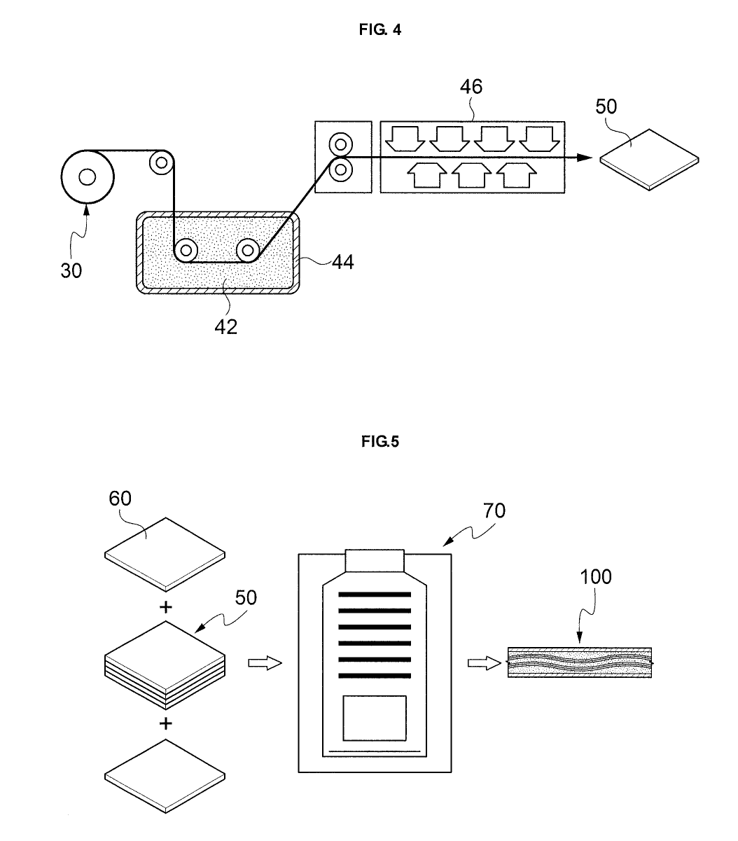

FIG. 2 is a flowchart showing a method for manufacturing a substrate raw material in accordance with an embodiment of the present invention, and FIGS. 3A, 3B, 4 and 5 are views for explaining a process of manufacturing a substrate raw material in accordance with an embodiment of the present invention.

Referring to FIGS. 2 and 3A and 3B, an organic fiber cloth may be manufactured using a super engineering polymer resin (S110). As an example, the step of manufacturing the organic fiber may be performed by a spinning method. As shown in FIG. 3A, the spinning method may manufacture a filament 14 by processing the super engineering resin using a spinneret that is rotatable in a heater 12. The manufactured filament 14 may be collected by a cylindrical winder 16 to be kept in roll form. As another example, the step of manufacturing the organic fiber may be performed by a blow molding method. As shown in FIG. 3B, the blow molding method may manufacture a filament 26 by processing the super engineering resin using an extruder 22 and passing the processed super engineering resin through a die 24. The manufactured filament 26 may be collected by a cylindrical winder 28 to be kept in roll form.

Here, the super engineering resin may be variously selected according to characteristics of the organic fiber to be manufactured. As an example, at least one super engineering polymer resin of polysulfone (PSU), polyetherimide (PEI), polyethersulfone (PES), polyphenylsulfone (PPSU), and polyamideimide (PAI) may be used to relatively improve low CTE characteristics of the substrate raw material to be manufactured. At this time, it is possible to further reduce the CTE of the substrate raw material by orientation when manufacturing the substrate raw material while applying a predetermined tension to the organic fiber cloth. As another example, at least one super engineering polymer resin of polyphenylsulfone (PPSU), polyetheretherketone (PEEK), and polyphthalamide (PPA), which has a melting point or a glass transition temperature of not less than 280° C., may be used to relatively improve rigidity characteristics of the substrate raw material to be manufactured.

As above, the organic fiber cloth 30 may be manufactured by weaving the organic fiber manufactured using a spinning method or a blow molding method.

Referring to FIGS. 2 and 4, a prepreg 50 may be manufactured using the organic fiber cloth 30 (S120). The step of manufacturing the prepreg 50 may include passing the organic fiber cloth 30 through an impregnation bath 44 in which a base resin 42 is melt and drying the organic fiber cloth 30 passing through the impregnation bath 44 by a dryer 46. Here, preferably, the base resin 42 may be a resin having the same or substantially the same properties as the polymer resin for the manufacture of the organic fiber cloth 30.

Referring to FIGS. 2 and 5, a substrate raw material 100 may be manufactured using the prepreg 50 (S130). The step of manufacturing the substrate raw material 100 may include manufacturing a core layer by laminating a plurality of prepregs 50, manufacturing a laminate by laminating copper foil layers 60 on both surfaces of the core layer, and manufacturing a copper clad laminate 100, which is described above with reference to FIG. 1, by performing pressing and heat treatment processes on the laminate using a heat treatment device 30.

Hereinafter, a substrate raw material and a method for manufacturing a circuit board in accordance with embodiments of the present invention will be described in detail. Here, duplicate descriptions of the substrate raw material 100 and the circuit board having the same in accordance with the above-described embodiments of the present invention may be omitted or simplified.

### Embodiment 1

### 1. Manufacture of Organic Fiber and Cloth

A polymer resin such as polysulfone (PSU), polyetherimide (PEI), polyethersulfone (PES), polyphenylsulfone (PPSU), or polyamideimide (PAI), which is a semi-crystal super engineering polymer resin, is used as a material of an organic fiber. This polymer resin is manufactured into a filament using a spinning method or a blow molding method, and the fiber itself is oriented by stretching the filament. At this time, in order to manufacture the fiber having a low CTE, spinning conditions and stretching conditions are changed to reduce the CTE of the fiber itself. Secondary stretching is performed to give rigidity to the fiber, thus increasing the orientation of the organic polymer resin used in the fiber. The fiber manufactured like this is manufactured into an organic cloth through a weaving process. A melting point of the organic component fiber should be 20° C. or at least 15° C. higher than that of a base resin. This is to prevent the organic component fiber from being melted when manufacturing a prepreg and a copper clad laminate.

### 2. Manufacture of Substrate Raw Material

The base resin and the cloth are bonded to each other by passing the cloth, which is manufactured using the organic fiber, through an impregnation bath in which the molten base resin and an inorganic filler are mixed. Spherical silica is used as the inorganic filler to reduce the CTE. A prepreg, which is an insulating material, is manufactured by drying the cloth after passing the cloth through the impregnation bath. Copper foils are applied to upper and lower surfaces of the manufactured prepreg and secondarily processed through thermal compression to manufacture a copper clad laminate having a desired thickness.

### 3. Manufacture of Printed Circuit Board

A printed circuit board is manufactured using the substrate raw material manufactured as above. The multilayer printed circuit board is manufactured using a conventional method for manufacturing a printed circuit board by forming a conductive via and a circuit pattern on the copper clad laminate and sequentially laminating thin films such as an interlayer insulating film.

### Embodiment 2

### 1. Manufacture of Organic Fiber and Cloth

A super engineering polymer resin such as polyphenylsulfone (PPSU), polyetheretherketone (PEEK) or polyphthalamide (PPA), which has a melting point or a glass transition temperature of not less than 280° C., is used as a material of an organic fiber. This polymer resin is manufactured into a filament using a spinning method or a blow molding method, and the fiber itself is oriented by stretching the filament. At this time, in order to manufacture the fiber having a low CTE, spinning conditions and stretching conditions are changed to reduce the CTE of the fiber itself. Secondary stretching is performed to give rigidity to the fiber, thus increasing the orientation of the organic polymer resin used in the fiber. The fiber manufactured like this is manufactured into an organic cloth through a weaving process. A melting point of the organic component fiber should be 20° C. or at least 15° C. higher than that of a base resin. This is to prevent the organic component fiber from being melted when manufacturing a prepreg and a copper clad laminate.

### 2. Manufacture of Substrate Raw Material

The base resin and the cloth are bonded to each other by passing the cloth, which is manufactured using the organic fiber, through an impregnation bath in which the molten base resin and an inorganic filler are mixed. Spherical silica is used as the inorganic filler to reduce the CTE. A prepreg, which is an insulating material, is manufactured by drying the cloth after passing the cloth through the impregnation bath. Copper foils are applied to upper and lower surfaces of the manufactured prepreg and secondarily processed through thermal compression to manufacture a copper clad laminate having a desired thickness.

### 3. Manufacture of Printed Circuit Board

A printed circuit board is manufactured using the substrate raw material manufactured as above. The multilayer printed circuit board is manufactured using a conventional method for manufacturing a printed circuit board by forming a conductive via and a circuit pattern on the copper clad laminate and sequentially laminating thin films such as an interlayer insulating film.

### Comparative Example

### 1. Manufacture of Organic Fiber and Cloth

A T-glass glass fiber having a relatively high ratio of SiO2 is used as a material of an organic fiber.

### 2. Manufacture of Substrate Raw Material

A base resin and a cloth are bonded to each other by passing the cloth, which is manufactured as above, through an impregnation bath in which the molten base resin and an inorganic filler are mixed. An epoxy resin is used as the base resin. At this time, spherical silica is used as an inorganic filler to reduce a CTE. A prepreg, which is an insulating material, is manufactured by drying the cloth after passing the cloth through the impregnation bath. Copper foils are applied to upper and lower surfaces of the manufactured prepreg and secondarily processed through thermal compression to manufacture a copper clad laminate having a desired thickness.

### 3. Manufacture of Printed Circuit Board

A printed circuit board is manufactured using the substrate raw material manufactured as above. The multilayer printed circuit board is manufactured using a conventional method for manufacturing a printed circuit board by forming a conductive via and a circuit pattern on the copper clad laminate and sequentially laminating thin films such as an interlayer insulating film.

Properties of the resultants manufactured by the above-described embodiments 1 and 2 and comparative example are shown in the following Tables 1 to 3.

TABLE 1
Comparison of properties of organic fibers

| Properties of | | | | | Comparative | |
|---|---|---|---|---|---|---|
| fibers | Embodiment 1 | | Embodiment 2 | | example | |
| Coefficient of | −1.5 | ppm/° C. | 1.8 | ppm/° C. | 2.5 | ppm/° C. |
| thermal | | | | | | |
| expansion (CTE) | | | | | | |
| Modulus | 67 | GPa | 92 | GPa | 86 | GPa |

TABLE 2
Comparison of properties of substrate raw
materials manufactured using organic fibers

| Properties of | | | | | Comparative | |
|---|---|---|---|---|---|---|
| fibers | Embodiment 1 | | Embodiment 2 | | example | |
| Coefficient of | 0.4 | ppm/° C. | 3.2 | ppm/° C. | 5 | ppm/° C. |
| thermal | | | | | | |
| expansion (CTE) | | | | | | |
| Modulus | 27 | GPa | 39 | GPa | 35 | GPa |

TABLE 3
Comparison of properties of substrate raw
materials manufactured using organic fibers

| Properties of | | | |
|---|---|---|---|
| fibers | Embodiment 1 | Embodiment 2 | Embodiment 3 |
| Precondition | OK | OK | OK |
| (MSL2a) | | | |
| TCC | OK | OK | OK |
| b-HAST | OK | OK | OK |
| Solder heat | OK | OK | OK |
| resistance | | | |

Referring to Tables 1 and 2, it is checked that the substrate raw material using the organic fiber component cloth like the present invention exhibits low CTE characteristics as a CTE of less than 5 ppm/° C. compared to the substrate raw material using the glass fiber component cloth. Particularly, through the embodiment 1, it is checked that the substrate raw material having a low CTE of not more than 1 ppm/° C., which cannot reach by the use of the glass fiber cloth, can be manufactured. Further, since the substrate raw material according to the present invention uses the organic fiber, it can minimize so-called glass protrusion that a fiber cloth is exposed to the outside through a via hole when forming the via hole using a CO2 laser drill and precisely adjust characteristics such as CTE and rigidity of the substrate raw material.

Referring to Table 3, it is checked that the properties of the substrate raw material according to the above-described embodiments of the present invention are on the same level as those of the comparative example. Therefore, it is checked that the substrate raw material according to the present invention exhibits the low CTE characteristics while maintaining the properties compared to the conventional case of using the glass fiber.

As described above, the substrate raw material 100 according to an embodiment of the present invention is manufactured using the organic fiber cloth to remarkably reduce the CTE compared to the substrate raw material manufactured using the glass fiber cloth. Accordingly, the substrate raw material according to the present invention has a CTE of less than 5 ppm/° C., even not more than 1 ppm/° C. and thus product reliability such as solder joint reliability can be greatly improved by similarly adjusting contraction and expansion of a semiconductor chip and a circuit board due to heat generated from the semiconductor chip mounted on the circuit board when implementing a semiconductor chip mounting circuit board using the substrate raw material according to the present invention.

The substrate raw material 100 according to an embodiment of the present invention manufactures both of the base resin and the cloth using the organic components. Thus, when processing a via hole using a CO2 laser drill, since CO2 absorption rates are similar to each other, it is possible to suppress so-called glass protrusion that the fiber cloth is protruded. Accordingly, the substrate raw material according to the present invention can reduce defects in a fill plating process for forming a via by preventing the so-called glass protrusion due to the CO2 laser processing performed for manufacture of a circuit board.

Further, the method for manufacturing a substrate raw material according to an embodiment of the present invention can manufacture a substrate raw material having a low CTE or high rigidity compared to the substrate raw material manufactured using the glass fiber cloth by manufacturing the organic fiber cloth using the super engineering polymer resin, impregnating the glass fiber cloth with the base resin and drying the glass fiber cloth to manufacture the prepreg, and manufacturing the copper clad laminate using the prepreg. Accordingly, the method for manufacturing a substrate raw material according to the present invention can greatly improve product reliability of a circuit board by manufacturing a substrate raw material having a relatively low CTE or high rigidity compared to the substrate raw material using the glass fiber cloth.

The substrate raw material according to the present invention has a CTE of less than 5 ppm/° C., even not more than 1 ppm/° C. and thus product reliability such as solder joint reliability can be greatly improved by similarly adjusting contraction and expansion of a semiconductor chip and a circuit board due to heat generated from the semiconductor chip mounted on the circuit board when implementing a semiconductor chip mounting circuit board using the substrate raw material according to the present invention.

The substrate raw material according to the present invention can reduce defects in a fill plating process for forming a via by preventing so-called glass protrusion due to CO2 laser processing performed for manufacture of a circuit board.

The method for manufacturing a substrate raw material according to the present invention can greatly improve product reliability of a circuit board by manufacturing a substrate raw material having a relatively low CTE or high rigidity compared to a substrate raw material using a glass fiber cloth.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A substrate raw material for manufacture of a circuit board, comprising:
an insulating layer; and
an organic fiber cloth disposed in the insulating layer.

2. The substrate raw material according to claim 1, wherein the insulating layer has a coefficient of thermal expansion of less than 5.0 ppm/° C.

3. The substrate raw material according to claim 1, wherein the insulating layer has a coefficient of thermal expansion of not more than 1.0 ppm/° C.

4. The substrate raw material according to claim 1, wherein the insulating layer and the organic fiber cloth are made of a polymer resin.

5. The substrate raw material according to claim 1, wherein the organic fiber cloth is made of at least one super engineering polymer resin of polysulfone (PSU), polyetherimide (PEI), polyethersulfone (PES), polyphenylsulfone (PPSU), and polyamideimide (PAI).

6. The substrate raw material according to claim 1, wherein the organic fiber cloth is made of at least one super engineering polymer resin of polyphenylsulfone (PPSU), polyetheretherketone (PEEK), and polyphthalamide (PPA), which has a melting point or a glass transition temperature of not less than 280° C.

7. The substrate raw material according to claim 1, wherein the substrate raw material is a copper clad laminate for manufacture of a circuit board used in a high frequency band of not less than 1 MHz.

8. The substrate raw material according to claim 1, wherein the substrate raw material is a prepreg for manufacture of a circuit board used in a high frequency band of not less than 1 MHz.

9. A circuit board comprising:
a core layer manufactured by processing a prepreg; and
a circuit layer disposed on the core layer, wherein the core layer comprises:
an insulating layer made of a resin material; and
an organic fiber cloth disposed in the insulating layer.

10. The circuit board according to claim 9, wherein the insulating layer has a coefficient of thermal expansion of less than 5.0 ppm/° C.

11. The circuit board according to claim 9, wherein the insulating layer has a coefficient of thermal expansion of not more than 1.0 ppm/° C.

12. The circuit board according to claim 9, wherein the insulating layer and the organic fiber cloth are made of a polymer resin.

13. The circuit board according to claim 9, wherein the organic fiber cloth is made of at least one super engineering polymer resin of polysulfone (PSU), polyetherimide (PEI), polyethersulfone (PES), polyphenylsulfone (PPSU), and polyamideimide (PAI).

14. The circuit board according to claim 9, wherein the organic fiber cloth is made of at least one super engineering polymer resin of polyphenylsulfone (PPSU), polyetheretherketone (PEEK), and polyphthalamide (PPA), which has a melting point or a glass transition temperature of not less than 280° C.

15. A method for manufacturing a substrate raw material, comprising:
manufacturing an organic fiber cloth using a super engineering polymer resin; and
manufacturing a prepreg by impregnating the organic fiber cloth with a base resin and drying the organic fiber cloth.

16. The method for manufacturing a substrate raw material according to claim 15, wherein manufacturing the organic fiber cloth comprises:
manufacturing an organic fiber using at least one resin of polysulfone (PSU), polyetherimide (PEI), polyethersulfone (PES), polyphenylsulfone (PPSU), and polyamideimide (PAI); and
weaving the organic fiber.

17. The method for manufacturing a substrate raw material according to claim 15, wherein manufacturing the organic fiber cloth comprises:
manufacturing an organic fiber using at least one resin of polyphenylsulfone (PPSU), polyetheretherketone (PEEK), and polyphthalamide (PPA), which has a melting point or a glass transition temperature of not less than 280° C.; and
weaving the organic fiber.

18. The method for manufacturing a substrate raw material according to claim 15, wherein the base resin and the organic fiber cloth are made of the same polymer resin.
